(19) United States
(12) Patent Application Publication
(10) Pub. No.: US 2007/0290189 A1
(43) Pub. Date: Dec. 20, 2007

(54) Light emitting device and method of manufacturing the same

(75) Inventors: Si-Chen Lee, Taipei (TW); Ming-Wei Tsai, Taipei (TW)

Correspondence Address: BIRCH STEWART KOLASCH & BIRCH, PO BOX 747, FALLS CHURCH, VA, 22040-0747, US

(73) Assignee: National Taiwan University

(21) Appl. No.: 11/591,640

(22) Filed: Nov. 2, 2006

(30) Foreign Application Priority Data
Jun. 14, 2006 (TW) 095121151

(51) Int. Cl. H01L 29/06

(52) U.S. Cl. 257/13

(57) ABSTRACT

The invention discloses a light emitting device including a substrate, a first metal layer, and an infrared light emitter. The substrate has a first surface, and the first metal layer is formed on the first surface of the substrate. The infrared light emitter is formed on the first metal layer and includes a dielectric metal interface consisting of a dielectric layer and a second metal layer. The first metal layer of the invention is capable of suppressing the background thermal radiation resulted from the substrate, such that the light emitting device can be operated at high temperature and then emits infrared with narrow bandwidth.

### BACKGROUND OF THE INVENTION

1. Field of the Invention

The present invention relates to a light emitting device and a method of manufacturing the same and, more particularly, to a light emitting device capable of suppressing the background thermal radiation resulted from the substrate, such that the light emitting device can be operated at high temperature and then emits infrared with narrow bandwidth.

2. Description of the Prior Art

The infrared light emitting device is mainly applied to the optical communication industry. Currently, the infrared light emitting device can only be manufactured by a few methods, such as epitaxial technology; and it uses semiconductor components, such as III-V semiconductors, as the raw materials. However, the infrared component with middle or long wavelength has to be operated at low temperature, so expensive cooling equipment is required. On the other hand, the infrared component can be manufactured by multi-layer structure, but the ratio of the full width at half maximum (FWHM) Δ λ to the peak λ is unideal.

Referring to FIGS. 1 and 2, FIG. 1A is a side view illustrating the infrared light emitting device 1 of the prior art. FIG. 1B is a top view illustrating the infrared light emitting device 1 shown in FIG. 1A. FIG. 2 is a diagram illustrating the spectrum of the infrared light emitting device 1 shown in FIG. 1A. The infrared light emitting device 1 shown in FIG. 1A has been disclosed by El-Kady et al. in “Photonics and Nanostructures—Fundamentals and Applications, Volume 1, Issue 1, 69-77 (2003)”. In the beginning, El-Kady et al. forms a periodic photo-resist on a silicon substrate 10 by a photo process. Afterward, a metal 12 and a protective layer (e.g. graphite) 14 are formed on the surface of the silicon substrate 10 by a vapor deposition process. Finally, a plurality of holes with a depth of 5 μm is formed on the silicon substrate 10 by a deep reactive ion etching process, so as to obtain a periodic surface texture. As shown in FIG. 1B, the periodic surface texture of the infrared light emitting device 1 is distributed in a hexagonal manner. In practical application, the thermal radiation of the silicon substrate 10 can be coupled to be in the form of surface plasmon (SP). As shown in FIG. 2, the ratio of the FWHM Δ λ to the peak λ is about 14.4%.

There are a lot of prior arts disclosed for the infrared light emitting device. The related prior arts refer to the following: [1] Pralle et al., Appl. Phys. Lett., vol. 81, 4685, 2002; [2] Enoch et al., Appl. Phys. Lett., vol. 86, 261101, 2005; [3] Lee, Fu, and Zhang, Appl. Phys. Lett., vol. 87, 071904, 2005; [4] A. Narayanaswamy and G. Chen, Physical Review, B 70, 125101, 2004; and [5] I. Celanovic, D. Perreault, and J. Kassakian, Physical Review, B 72, 075127, 2005.

Furthermore, any object will generate thermal radiation at a specific temperature. When photonic crystals are used to manufacture an infrared light emitting device, the biggest challenge is to suppress the background thermal radiation outside a specific range, so as to manufacture the infrared light emitting device with narrow and adjustable bandwidth. That is to say, how to suppress the background thermal radiation outside a specific range is the most difficult.

Therefore, the scope of the invention is to provide a light emitting device and a method of manufacturing the light emitting device capable of suppressing the background thermal radiation resulted from the substrate, so as to solve the aforementioned problems.

### SUMMARY OF THE INVENTION

A scope of the invention is to provide a light emitting device and a method of manufacturing the same, such that the thermal radiation can be controlled to extract the useful spectrum, and the background thermal radiation resulted from the substrate can be suppressed. Accordingly, the light emitting device can be operated at high temperature, and it emits infrared with narrow bandwidth.

According to a preferred embodiment, the light emitting device of the invention comprises a substrate, a first metal layer, and an infrared light emitter. The substrate has a first surface, and the first metal layer is formed on the first surface of the substrate. The infrared light emitter is formed on the first metal layer and comprises a dielectric metal interface consisting of a dielectric layer and a second metal layer.

In practical application, the first metal layer of the invention has a high reflective coefficient and a low emissivity, such that it is capable of suppressing the background thermal radiation resulted from the substrate. Moreover, the blackbody radiation of the first metal layer is very little, so that the infrared light emitter can emit infrared with narrow bandwidth, and the wavelength of the emitted infrared is longer than 0.8 μm. Accordingly, the light emitting device of the invention can be operated at high temperature, and it emits infrared with narrow bandwidth.

The advantage and spirit of the invention may be understood by the following recitations together with the appended drawings.

### BRIEF DESCRIPTION OF THE APPENDED DRAWINGS

FIG. 1A is a side view illustrating the infrared light emitting device of the prior art.

FIG. 1B is a top view illustrating the infrared light emitting device shown in FIG. 1A.

FIG. 2 is a diagram illustrating the spectrum of the infrared light emitting device shown in FIG. 1A.

FIG. 3A is a top view illustrating the light emitting device according to a preferred embodiment of the invention.

FIG. 3B is a sectional view illustrating the light emitting device along the line X-X shown in FIG. 3A.

FIG. 4 is a diagram illustrating the spectrum of the light emitting device shown in FIG. 3B.

FIGS. 5A through 5E illustrates the process of manufacturing the light emitting device shown in FIG. 3B.

FIG. 6 is a top view illustrating the light emitting device according to another preferred embodiment of the invention.

FIG. 7 is a schematic diagram illustrating the light emitting device according to another preferred embodiment of the invention.

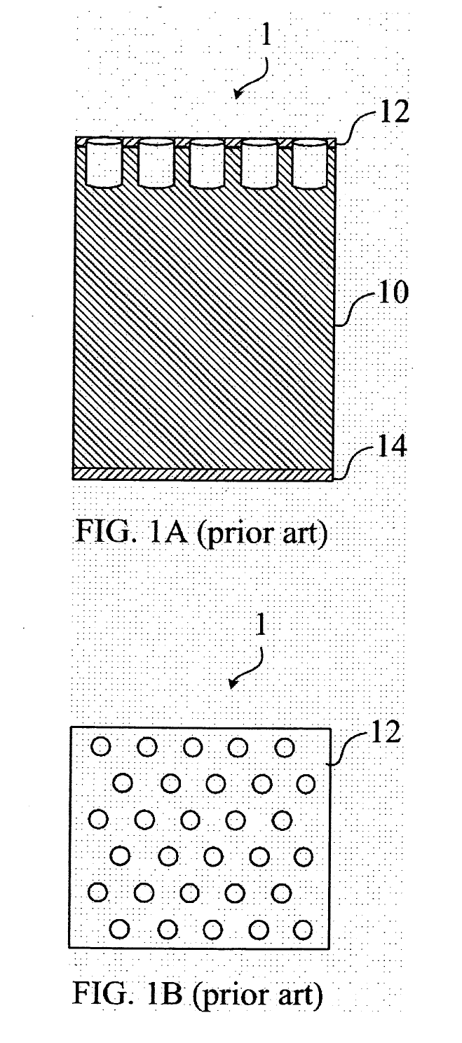

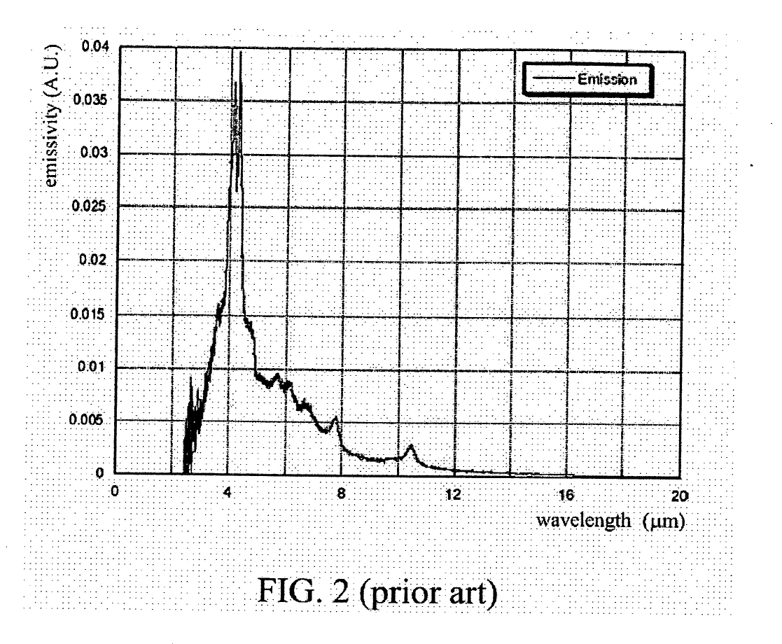

### DETAILED DESCRIPTION OF THE INVENTION

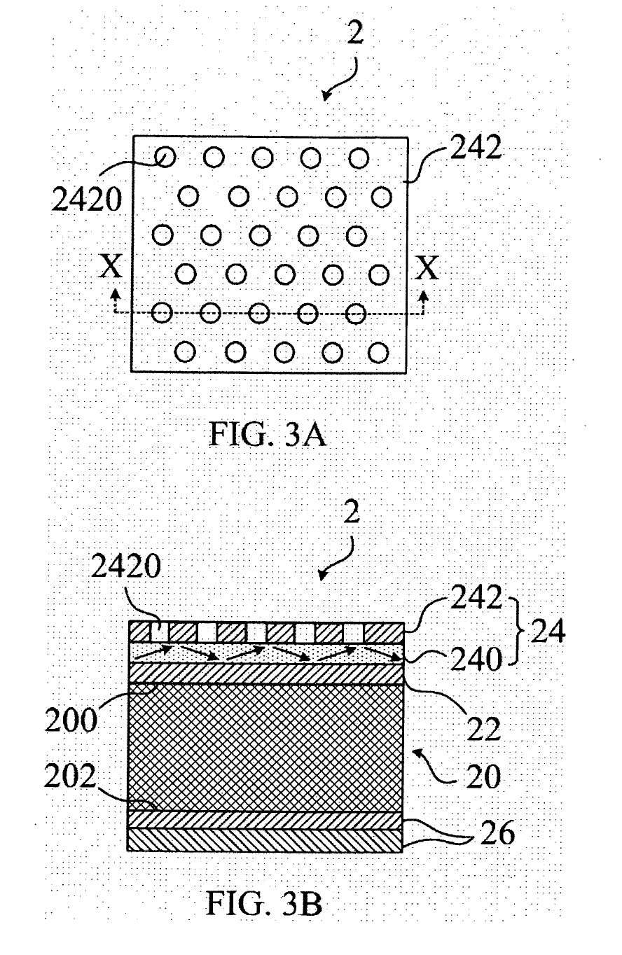

Referring to FIG. 3, FIG. 3A is a top view illustrating the light emitting device 2 according to a preferred embodiment of the invention. FIG. 3B is a sectional view illustrating the light emitting device 2 along the line X-X shown in FIG. 3A. As shown in FIG. 3B, the light emitting device 2 comprises a substrate 20, a first metal layer 22, an infrared light emitter 24, and at least one third metal layer 26. The infrared light emitter 24 comprises a dielectric metal interface consisting of a dielectric layer 240 and a second metal layer 242. In this embodiment, the substrate 20 can be a glass substrate, an insulating substrate, a semiconductor substrate, or the like with thermal conductivity. The material of the first metal layer 22 can be Ag, Au, Al, Pt, Cr, Ti, W, Ta, Cu, Co, Ni, Fe, Mo, or the like with high reflectivity. The material of the dielectric layer 240 can be oxide, nitride, other dielectric materials, or other insulating materials. The material of the second metal layer 242 can be Ag, Au, Al, Pt, Cr, Ti, W, Ta, Cu, Co, Ni, Fe, Mo, or the like with high reflectivity. The material of the third metal layer 26 can be Cr, Au, W, or other thermal-resisting conductive materials.

As shown in FIG. 3B, the substrate 20 has a first surface 200 and a second surface 202. The first metal layer 22 is formed on the first surface 200 of the substrate 20. The infrared light emitter 24 is formed on the first metal layer 22. The third metal layer 26 is formed on the second surface 202 of the substrate 20. In this embodiment, the light emitting device comprises but is not limited to two third metal layers 26.

The second metal layer 242 has a plurality of first holes 2420 formed thereon. Each of the first holes 2420 is periodically distributed over the second metal layer 242. In this embodiment, the first holes 2420 are periodically distributed over the second metal layer 242 in a hexagonal manner, as shown in FIG. 3A.

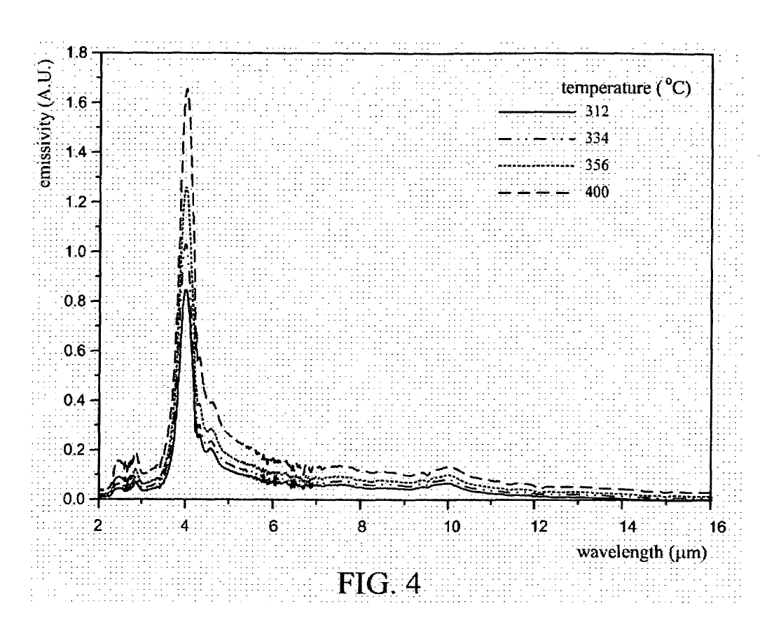

Referring to FIG. 4, FIG. 4 is a diagram illustrating the spectrum of the light emitting device 2 shown in FIG. 3B. When the third metal layer 26 is conducted with a current, the spectrum diagram shown in FIG. 4 can be measured from the front of the light emitting device 2. The dielectric layer 240 can be used as a radiation source and a resonance cavity. When the light emitting device 2 is heated, the thermal radiation emitted by the dielectric layer 240 will be restrained and resonated between the first metal layer 22 and the second metal layer 242, so as to induce the surface plasmon resulted from the dielectric/metal layer and the air/metal layer. The surface plasmon will be released in the form of light finally. As shown in FIG. 4, the position at 4 μm shows a degeneracy surface plasmon mode of the dielectric/metal layer in (1, 0), (0, 1), (−1, 1), (−1, 0), (0, −1), (1, −1); the position at 2.5 μm shows a degeneracy surface plasmon mode of the dielectric/metal layer in (1, 1), (−1, 2), (−2, 1), (−1, −1), (1, −2), (2, −1), and the position at 3 μm shows a degeneracy surface plasmon mode of the air/metal layer in (1, 0), (0, 1), (−1, 1), (−1, 0), (0, −1), (1, −1).

In this embodiment, the first metal layer 22 formed on the first surface 200 of the substrate 20 is used as a background radiation reflective layer capable of reflecting the thermal radiation resulted from the substrate 20 and the dielectric layer 24. The second metal layer 242 with the periodic surface texture is used as a resonance cavity reflective layer and a surface plasmon inducing layer. When the light emitting device 2 is heated, the background thermal radiation resulted from the substrate 20 will be fully blocked by the first metal layer 22. Since the emissivity of the first metal layer (e.g. Ag) is very low, it will not emit a lot of background radiation. The thermal radiation of the dielectric layer 240 is transmitted between the first metal layer 22 and the second metal layer 242, so as to induce the surface plasmon resulted from the dielectric/metal layer or the air/metal layer. Afterward, the surface plasmon will release light through the periodic surface texture of the second metal layer 242. After the thermal radiation is resonated repeatedly, the thermal radiation spectrum with a specific wavelength will be greatly increased, and then it is released in the form of light. In practical experiment based on the light emitting device 2 of the invention, the ratio of the FWHM Δ λ to the peak λ can be reduced to be about 10%. Accordingly, the light emitting device 2 of the invention can be operated at high temperature and then emits infrared with narrow bandwidth.

In practical application, the infrared light emitter 24 is capable of emitting an infrared with a wavelength longer than 0.8 μm.

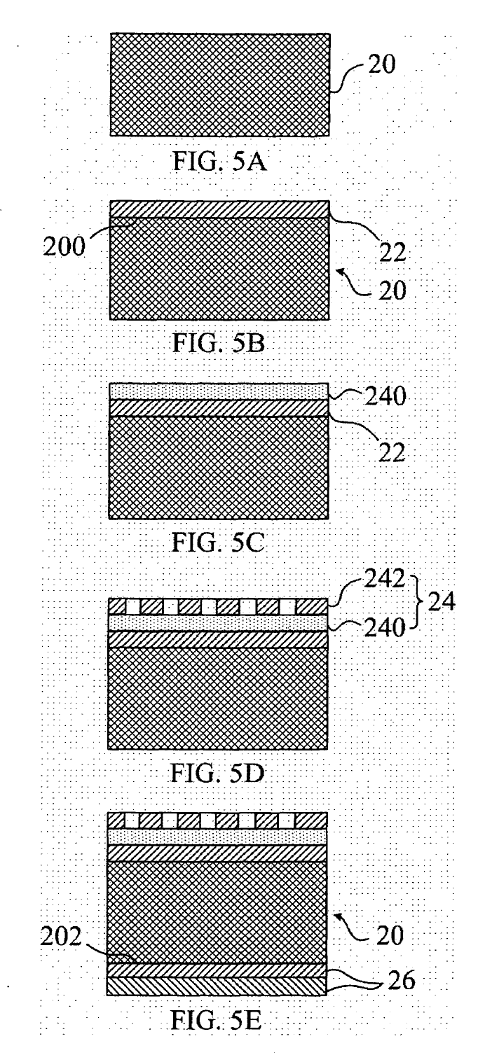

Referring to FIGS. 5A through 5E, FIGS. 5A through 5E illustrates the process of manufacturing the light emitting device 2 shown in FIG. 3B. The method of the invention for manufacturing the light emitting device 2 comprises the following steps. At the start, as shown in FIG. 5A, the substrate 20 is provided. Afterward, as shown in FIG. 5B, the first metal layer 22 is formed on the first surface 200 of the substrate 20 by a vapor deposition process, wherein the first metal layer 22 is but not limited to Ag, and the thickness thereof is but not limited to 100 nm. As shown in FIG. 5C, the dielectric layer 240 is formed on the first metal layer 22 by the vapor deposition process, wherein the dielectric layer 240 is but not limited to oxide (e.g. SiO₂), and the thickness thereof is but not limited to 100 nm. As shown in FIG. 5D, the second metal layer 242 with periodic surface texture is formed on the dielectric layer 240 by a lithography process, so as to form the infrared light emitter 24. Preferably, the second metal layer 242 is but not limited to Ag, and the thickness thereof is but not limited to 100 nm. Finally, as shown in FIG. 5E, the third metal layer 26 is formed on the second surface 202 of the substrate 20 by a vapor deposition process, wherein the third metal layer 26 is but not limited to consisting two metal layers, such as Cr and Au, and the thickness of each metal layer 26 is but not limited to 50 nm and 100 nm. Accordingly, the manufacture of the aforesaid light emitting device 2 is completed.

In another preferred embodiment of the invention, the infrared light emitter 24 of the light emitting device 2 can also be manufactured to be multi-layer structure according to the process shown in FIGS. 5A through 5E.

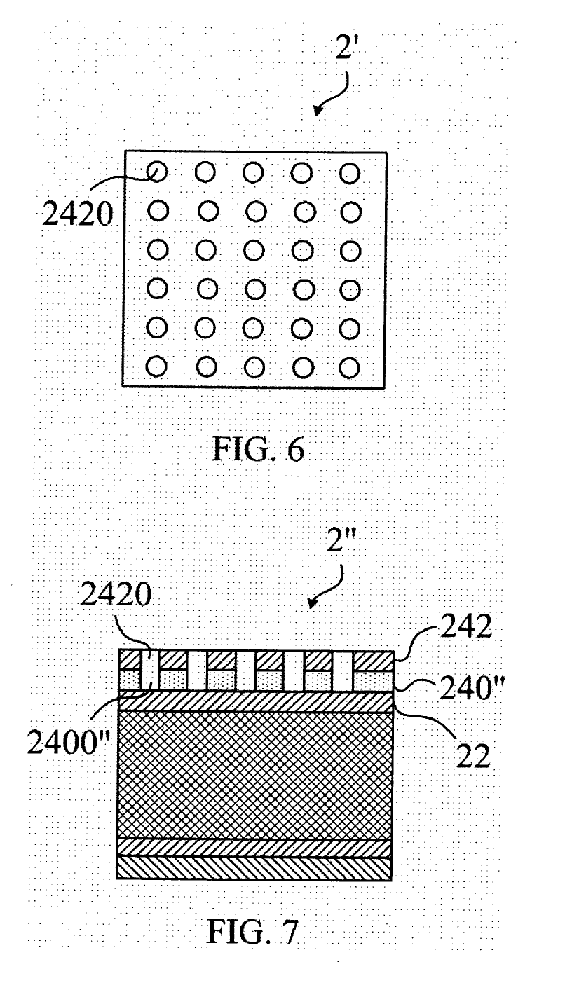

Referring to FIG. 6, FIG. 6 is a top view illustrating the light emitting device 2′ according to another preferred embodiment of the invention. The main difference between the light emitting device 2′ and the light emitting device 2 is that the first holes 2420 of the light emitting device 2′ are periodically distributed in a square manner, as shown in FIG. 6. The function and principle of the light emitting device 2′ shown in FIG. 6 are the same as the light emitting device 2 shown in FIG. 3A, and the related description will not be mentioned here.

Referring to FIG. 7, FIG. 7 is a schematic diagram illustrating the light emitting device 2″ according to another preferred embodiment of the invention. The main difference between the light emitting device 2″ and the light emitting device 2 is that the dielectric layer 240″ of the light emitting device 2″ has a plurality of second holes 2400″ formed thereon, and each of the second holes 2400″ corresponds to one of the first holes 2420. In other words, the second holes 2400″ are also periodically distributed over the dielectric layer 240″, as shown in FIG. 7. In this embodiment, the dielectric layer 240″ is formed on the first metal layer 22 by a lithography process, so as to form the same periodic surface texture as the second metal layer 242. The function and principle of the light emitting device 2″ shown in FIG. 7 are the same as the light emitting device 2 shown in FIG. 3B, and the related description will not be mentioned here.

Compared to the prior art, the first metal layer of the light emitting device according to the invention is capable of suppressing the background thermal radiation resulted from the substrate, such that the light emitting device can be operated at high temperature and then emits infrared with narrow bandwidth.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A light emitting device comprising:
a substrate having a first surface;
a first metal layer formed on the first surface of the substrate; and
an infrared light emitter, formed on the first metal layer, comprising a dielectric metal interface consisting of a dielectric layer and a second metal layer.

2. The light emitting device of claim 1, wherein the infrared light emitter is capable of emitting an infrared with a wavelength longer than 0.8 μm.

3. The light emitting device of claim 1, wherein the second metal layer has a plurality of first holes formed thereon.

4. The light emitting device of claim 3, wherein the first holes are periodically or non-periodically distributed over the second metal layer.

5. The light emitting device of claim 4, wherein the first holes are periodically distributed over the second metal layer in a hexagonal manner.

6. The light emitting device of claim 4, wherein the first holes are periodically distributed over the second metal layer in a square manner.

7. The light emitting device of claim 4, wherein the first holes are randomly distributed over the second metal layer.

8. The light emitting device of claim 3, wherein the dielectric layer has a plurality of second holes formed thereon, and each of the second holes corresponds to one of the first holes.

9. The light emitting device of claim 8, wherein the second holes are periodically or non-periodically distributed over the dielectric layer.

10. The light emitting device of claim 1, wherein the substrate is a material with thermal conductivity.

11. The light emitting device of claim 10, wherein the substrate is one selected from a group consisting of a glass substrate, an insulating substrate, and a semiconductor substrate.

12. The light emitting device of claim 1, wherein the first layer is one selected from a group consisting of Ag, Au, Al, Pt, Cr, Ti, W, Ta, Cu, Co, Ni, Fe, and Mo.

13. The light emitting device of claim 1, wherein the second layer is one selected from a group consisting of Ag, Au, Al, Pt, Cr, Ti, W, Ta, Cu, Co, Ni, Fe, and Mo.

14. The light emitting device of claim 1, wherein a material of the dielectric layer is oxide or nitride.

15. The light emitting device of claim 1, further comprising at least one third metal layer formed on a second surface of the substrate.

16. The light emitting device of claim 15, wherein the third metal layer is a conductive material.

17. A method for manufacturing a light emitting device comprising the steps of:
(a) providing a substrate having a first surface;
(b) forming a first metal layer on the first surface of the substrate; and
(c) forming an infrared light emitter on the first metal layer, wherein the infrared light emitter comprises a dielectric metal interface consisting of a dielectric layer and a second metal layer.

18. The method of claim 17, wherein the infrared light emitter is capable of emitting an infrared with a wavelength longer than 0.8 μm.

19. The method of claim 17, wherein the first metal layer is formed on the substrate by a vapor deposition process.

20. The method of claim 17, wherein the step (c) comprises the steps of:
(c1) forming the dielectric layer on the first metal layer; and
(c2) forming the second metal layer on the dielectric layer.

21. The method of claim 20, wherein the dielectric layer is formed on the first metal layer by a vapor deposition process.

22. The method of claim 20, wherein the second metal layer has a plurality of first holes formed thereon.

23. The method of claim 22, wherein the second metal layer is formed on the dielectric layer by a lithography process.

24. The method of claim 23, wherein the first holes are periodically or non-periodically distributed over the second metal layer.

25. The method of claim 24, wherein the first holes are periodically distributed over the second metal layer in a hexagonal manner.

26. The method of claim 24, wherein the first holes are periodically distributed over the second metal layer in a square manner.

27. The method of claim 24, wherein the first holes are randomly distributed over the second metal layer.

28. The method of claim 24, wherein the dielectric layer has a plurality of second holes formed thereon, and each of the second holes corresponds to one of the first holes.

29. The method of claim 28, wherein the dielectric layer is formed on the first metal layer by a lithography process.

30. The method of claim 28, wherein the second holes are periodically or non-periodically distributed over the second metal layer.

31. The method of claim 17, further comprising the step of forming at least one third metal layer on a second surface of the substrate.

32. The method of claim 31, wherein the third metal layer is formed on the second surface of the substrate by a vapor deposition process.
